(19) United States
(12) Patent Application Publication
(10) Pub. No.: US 2008/0203483 A1
(43) Pub. Date: Aug. 28, 2008

(54) SEMICONDUCTOR DEVICE INCLUDING A RECESSED-CHANNEL-ARRAY MISFET

(75) Inventor: Keiji KUROKI, Tokyo (JP)

Correspondence Address: YOUNG & THOMPSON, 209 Madison Street, Suite 500, ALEXANDRIA, VA, 22314, US

(73) Assignee: ELPIDA MEMORY, INC., TOKYO (JP)

(21) Appl. No.: 12/036,439

(22) Filed: Feb. 25, 2008

(30) Foreign Application Priority Data
Feb. 26, 2007 (JP) 2007-045300

(51) Int. Cl. H01L 21/336; H01L 29/78

(52) U.S. Cl. 257/368; 438/282; 257/E21.409; 257/E29.27

(57) ABSTRACT

A semiconductor device includes RCA MISFETs formed in active regions of a semiconductor substrate, the active regions being defined by shallow-trench-isolation (STI) structure. The top surface of the insulating film is flush with the top surface of the active regions. The gate electrode of each MISFET includes a first portion at extends over the top surface of the insulating film of the STI structure, and a second portion embedded in a gate trench formed in the active region.

This application is based upon and claims the benefit of priority from Japanese patent application No. 2007-045300, the disclosure of which is incorporated herein in its entirety by reference.

### BACKGROUND OF THE INVENTION

1. Field of the Invention

The present invention relates to a semiconductor device and a method for manufacturing the same, and more particularly, to a semiconductor device including a recessed-channel-array (RCAT) MISFET formed on a semiconductor substrate and a method for manufacturing the same.

2. Description of the Related Art

A DRAM (Dynamic Random Access Memory) device includes an array of memory cells for storage of information therein. The memory cells include a MISFET (Metal-Insulator-Semiconductor Field Effect Transistor) formed on a surface region of a semiconductor substrate and a capacitor connected to the MISFET. The memory cells store charge in the capacitor via the MISFET to hold data therein.

In recent years, together with higher integration density of DRAM devices, the line width of interconnections in the DRAM devices has been drastically reduce. It the MISFETs, the reduction in the line width has caused to reduce the distance between the source/drain diffused regions which sandwich therebetween a gate electrode. In such circumstances, it is necessary to prevent occurring of a so-called short channel effect.

One of the countermeasures for preventing the short channel effect is to provide a recessed-channel-array (RCAT) MISFET instead of the conventional MISFETs. The RCAT MISFETs considerably differ from the conventional planar MISFETs and have a structure such that an impurity-doped polycrystalline silicon layer configuring apart of the gate electrode is recessed, i.e., is formed within a trench, which is referred to as gate trench hereinafter. The gate trench is formed on the surface region of a silicon substrate.

In the structure of the RCAT MISFETs, the channel of the MISFETs is formed along the bottom and side surfaces of the gate trench. This assures a longer effective channel length of the MISFETs, thereby suppressing the short channel effect Patent Publications JP07-38095-A1 and JP-2004-71733-A1, for example, describe the structure of the RCAT MISFETs and method for forming the same.

The MISFETs in the DRAM device are isolated from one another by an element-isolation structure known as a shallow-trench-isolation (STI) structure formed on the surface region of the silicon substrate. The STI structure is employed in the view point of easiness in the micro-fabrication of the STI structure, and includes an isolation film embedded in a shallow trench formed on the surface region of the silicon substrate. Meanwhile, there has been the problem of occurring of a void in the STI structure having a smaller trench width. The void is formed within the isolation film in tile STI structure during step of embedding the isolation film in the isolation trench. This is because the width of the isolation trench is drastically reduced along it the reduction in the line width of the DRAM device. The void formed in the STI structure generally has an elongate shape extending along the longitudinal direction of the isolation trench, which configures a boundary area between two adjacent active regions receiving therein the MISFETs.

In the conventional technique for manufacturing the MISFETs, the isolation film within the isolation trench is etched together with the surface portion of the silicon substrate during the step of forming the gate trenches of the RCAT MISFETs. FIGS. 8A and 8B show the problem of the void in the conventional technique for forming the RCAT MISFETs. The isolation film 13 is embedded in the isolation trench formed on the surface region of the silicon substrate 11. As shown in FIG. 8A, the gate trenches 16 of a U-character shape are formed by etching using a hard mask 32 as an etching mask, whereby the gate trenches 16 are formed to extend on the surface of the silicon substrate 11 as well as the surface of the isolation film 13.

In the example of FIG 8A, the isolation film 13 receives therein a void 31 extending perpendicular to the gate trenches. In the etching process for forming the gate trenches in the isolation region, the void 31 may be exposed from the bottom of the gate trench 16. After the gate electrodes 15 each including a polysilicon film 17 and a tungsten film 18 are formed in the gate trenches and above the gate trenches, the void 31 may receive therein the deposited polysilicon. Thus, adjacent gate electrodes may be short-circuited via the void 31 receiving therein the polysilicon layer of the gate electrode 15.

### SUMMARY OF THE INVENTION

The present invention has been made in view of the foregoing circumstances, and it is therefore an object of the present invention to provide a semiconductor device including an RCAT MISFET and a method for manufacturing the same, the semiconductor device being capable of suppressing the occurring of a short-circuit failure due to a void formed in the isolation film of the STI structure.

The present invention provides a method for manufacturing a semiconductor device including: forming an isolation region on a surface region of a semiconductor substrate to define an array of active regions isolated from one another; forming a mask having a pattern including a plurality of first stripes extending parallel to one another, the first stripes each extending over a portion of the active regions arranged in a row, and a plurality of second stripes extending parallel to one another to intersect the first stripes, the second stripes each extending over a portion of the isolation region located between adjacent columns of the active regions; selectively etching the active regions by using the mask as an etching mask, to form a gate trench in each of active regions; forming MISFETs each including source/drain regions in one of the active regions and a gate electrode received in the gate trench formed in the one of the active regions.

The present invention also provides a semiconductor device including: a semiconductor substrate; an isolation region defining an array of active regions on the semiconductor substrate, the active regions having a top surface flush with a top surface of the isolation region and including a gate trench therein; a plurality of MISFETs formed in the respective active regions, a row of the MISFETs including a gate electrode having a first portion extending on the top surface of the isolation region and a second portion embedded in the gate trench.

The above and other object, features and advantages of the present invention will be more apparent from the following description, referring to the accompanying drawings.

### BRIEF DESCRIPTION OF THE DRAWINGS

FIG. 1 is atop plan view showing the structure of a semiconductor device according to an embodiment of the present invention;

FIGS. 2A and 2B are sectional views taken along arrowed lines A-A and B-B, respectively, in FIG. 1;

FIGS. 3A to 6A are sectional views of the semiconductor device of FIG. 1 in consecutive steps of a process for manufacturing the semiconductor device, taken along arrowed line A-A in FIG. 1;

FIGS. 3B to 6B are sectional views taken along arrowed line B-B in FIG. 1 in consecutive steps corresponding to the steps of FIGS. 3A to 6A, respectively;

FIG. 7 is a top plan view of the semiconductor device of FIG. 1 in the step corresponding to the step of FIGS. 5A and 5B;

FIGS. 8A and 8B are sectional views of a semiconductor device in consecutive steps of a conventional process for manufacturing the semiconductor device; and

FIG. 9 is a sectional view taken along arrowed line IX-IX in FIG. 8A.

### DETAILED DESCRIPTION OF THE INVENTION

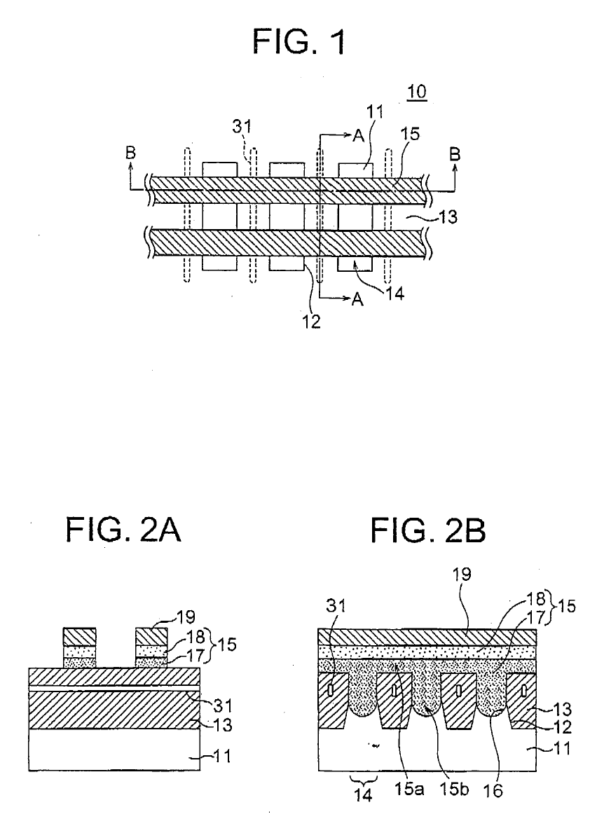

Hereinafter, an exemplary embodiment of the present invention will be described in more detail with reference to the accompanying drawings. FIG. 1 is a top plan view showing the structure of a semiconductor device according to the embodiment of the present invention. The semiconductor device 10 is configured as a DRAM device and includes a silicon substrate 11. In the surface region of the silicon substrate 11, a shallow-trench-isolation (STI) structure is formed including an isolation trench 12 and an isolation film 13 embedded therein, to thereby separate the surface region of the semiconductor substrate 11 into active regions 14. The active regions 14 have an elongate shape having a longer side in the column direction, and receive therein source/drain diffused regions of MISFETs. The isolation film 13 is made of silicon oxide deposited using a high-density-plasma-enhanced chemical vapor deposition (HDP-CVD) technique, for example. The top surface of the isolation film 13 is polished to be flush with the top surface of the silicon substrate 11 in the active regions 14.

Above the silicon substrate 11, gate electrodes 15 of the MISFETs extend in the row direction to cross the active regions 14 arranged in the row direction. One active region 14 is crossed by two gate electrodes 15 and thereby two MISFETs are formed therein, which share a central source diffused region and have respective drain diffused regions sandwiching therebetween the shared source diffused region.

FIGS. 2A and 2B are sectional views taken along arrowed lines A-A and B-B, respectively, in FIG. 1. After the isolation film 13 is deposited in the isolation trenches 12, a void 31 may be formed in a portion of the isolation film 13 depending on the dimensional condition of the isolation trenches 12 or process condition for the deposition. The void 31 generally extends in the column direction of the isolation film 13 or along the longer side of the adjacent active regions 14.

The MISFETs formed in the active regions 14 are RCAT MISFETs, wherein the gate trenches 16 are formed in a surface region of the silicon substrate 11 at the portion where the gate electrodes 15 and active regions 14 overlap each other. The bottom portion of the gate electrodes 15 is received in the gate trenches 16. More specifically, the gate electrodes 15 include a first portion 15a that extends on the top surface of the isolation film 13 formed to have the same height as the top surface of the silicon substrate 11 in the active regions 14, and a second portion 15b that extends downward from the first portion 15a so as to be embedded in the gate trenches 16 formed in the active regions 14.

A gate oxide film (not shown) is interposed between the silicon substrate 11 and the gate electrode 15. In the RCAT MISFETs, the channel of the MISFETs extends along the bottom and side surface of the gate trenches 16 in the longitudinal direction of the active regions 14.

The gate electrodes 15 have a two-layer structure including an impurity-doped polysilicon layer 17 as a lower layer and a tungsten layer 18 as an upper layer, wherein the bottom portion of the polysilicon layer 17 is received in the gate trench 16. A cap protective film 19 made of silicon nitride is formed on top of the gate electrodes 15, and a sidewall protective film (not shown) made of silicon nitride is formed on the side surface of the gate electrodes 15.

An interlayer dielectric film (not shown) is formed over the entire area of the silicon substrate 11 including the isolation film 13 of the STI structure and MISFETs including the gate electrodes 15. Contact plugs penetrate the interlayer dielectric film so as to be in contact with the source/drain diffused regions of the MISFETs. Above the interlayer dielectric film, bit lines and cell capacitors are formed which are connected to the contact plugs directly or via conductive plugs.

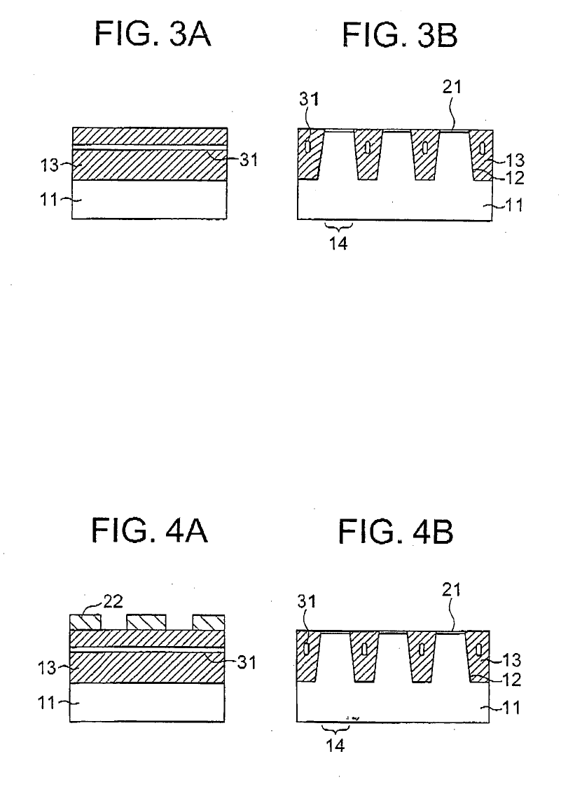

Now, a process for manufacturing the semiconductor device of FIG. 1 will be described. FIGS. 3A to 6A as well as FIGS. 3B to 6B are sectional views consecutively showing the steps of the process for manufacturing the semiconductor device 10 shown in FIG. 1 and FIGS. 2A and 2B. The sectional structure depicted in FIGS. 3A to 6A corresponds to the sectional shown in FIG. 2A, whereas the sectional structure depicted in FIGS. 3B to 6B correspond to the sectional structure shown in FIG. 2B.

Using a thermal oxidation technique, a silicon oxide film (thermal oxide film) 21 is formed on the surface of the silicon substrate 11, and thereafter a silicon nitride film (not shown) is formed on the thermal oxide film 21. A photoresist film including patterns having a planar shape corresponding to the active regions 14 is formed on the silicon nitride film. Thereafter, the silicon nitride film is patterned by etching using the photoresist film pattern as an etching mask to thereby form a hard mask covering the active regions 14. Further, a dry etching process using the patterned silicon nitride film or hard mask is performed onto the surface portion of the thermal oxide film 21 and silicon substrate 11, whereby the isolation trenches 12 are formed having a depth of 200 to 300 nm.

Thereafter, using a HDP-CVD technique, a silicon oxide film is deposited over the entire surface of the silicon substrate 11 inclusive of the interior of the isolation trenches 12 so as to have a film thickness of about 500 nm. In the deposition of the silicon oxide film, a void 31 may be formed in the isolation trenches 12 depending on the dimensional condition of the isolation trenches 12 or process condition of the deposition Subsequently, a CMP process is conducted for planarization while using the silicon nitride film as an etch stopper, which has been used as the etching mask for etching to form the isolation trenches 12, whereby the STI structure including the isolation trenches 12 and isolation film 13 formed in the isolation trenches separates the silicon substrate 11 into a plurality of active regions 14. Further, a wet etching process using thermal phosphoric acid is performed to remove the silicon nitride film (FIGS. 3A and 3B).

Subsequently, a silicon nitride film is deposited over the entire surface of the silicon substrate 11 and isolation film 13 of the STI structure. Over the silicon nitride film, a photoresist film pattern is formed which expose the portion where the gate electrodes 15 are to be formed, and then the silicon nitride film is patterned by dry etching using the photoresist film pattern as an etching mask, thereby forming a hard mask pattern 22 having a plurality of stripes extending in the row direction (FIGS. 4A and 4B).

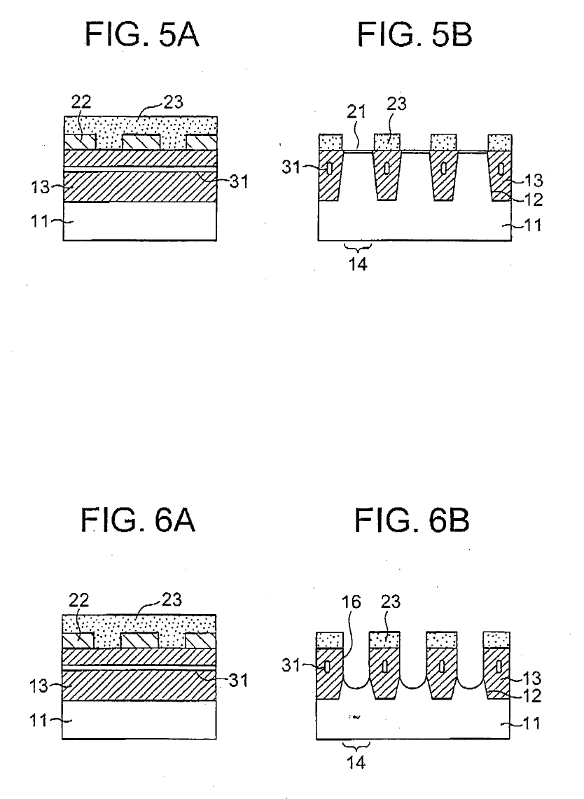

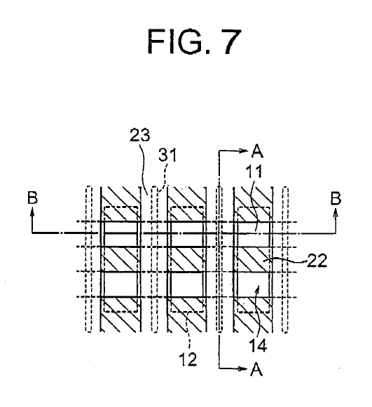

Subsequently, as shown in FIGS. 5A and 5B, a photoresist mask pattern 23 is formed on the isolation film 13, covering the hard mask pattern 22. The photoresist mask pattern 23, as shown in FIG. 7 as a top plan view, includes a plurality of stripes extending in the column direction, covering the insulating film 13 of the STI structure and exposing the active regions 14. That is, the stripes of the photoresist mask pattern 23 extend perpendicular to the extending direction of the stripes of the hard mask pattern 22.

Thereafter, a dry etching process using the hard mask pattern 22 and photoresist mask pattern 23 as an etching mask is performed onto the surface region of the silicon substrate 11, whereby gate trenches 16 having a depth of 100 to 150 nm and shown in FIG. 6B are formed. The dry etching is carried out using an etching gas including a mixture of Cl₂, O₂ and N₂, wherein the flow rates of Cl₂, O₂ and N₂ are set at 200, 20 and 20 sccm (standard cubic centimeters), with the internal pressure of the etching chamber being set at 30 mTorr. Further, the source power is set at 800 W, the bias power at 300 W and the etching time for 20 seconds.

In the dry etching process as described above, the isolation film 13 is not etched because the photoresist mask pattern 23 is formed thereon. Thus, the voids 31, if formed, are not exposed within the gate trenches 16 or on the top surface of the isolation film 13. Subsequently, the hard mask pattern 22 and photoresist mask pattern 23 are removed.

Thereafter, specific types of impurity ions are implanted into the surface region of the silicon substrate 11 inclusive of the internal of the gate trenches 16, to form the channel of the MISFETs. In addition, a gate oxide film (not shown) is formed on the surface of the silicon substrate 11 inclusive of the bottom and side surface of the gate trenches 16. Prior to the formation of the gate oxide film, the thermal oxide film 21 is subjected to pre-treatment where the thermal oxide film 21 is removed by wet etching. Subsequently, the polysilicon layer 17, tungsten layer 18 and silicon nitride layer are consecutively deposited over the silicon substrate 11 inclusive of the gate trenches 16 and isolation film 13. The deposition of the polysilicon layer 17 may completely fill up the gate trenches 16.

Subsequently, a photoresist mask pattern is formed over the silicon nitride layer to cover the region thereof in which the gate electrodes 15 are to be formed. The silicon nitride layer is then subjected to a patterning process by dry etching using the photoresist mask, thereby forming the top protective film 19 for the gate electrodes. Further, through dry etching using the top protective film 19 as a mask, the polysilicon layer 17 and tungsten layer 18 are patterned to thereby form the gate electrodes 15 shown in FIGS. 2A and 2B.

Using the protective film 19 as a mask, impurity ions are implanted into the surface region of the silicon substrate 11 adjacent to the gate electrodes 15 to form the source/drain diffused regions. This process provides the MISFETs configured by the gate electrodes 15 and the source/drain diffused regions, which are located adjacent to the gate electrodes 15. After deposition of the interlayer dielectric film over the silicon substrate 11 inclusive of the gate electrodes 15 and isolation film 13, the plugs to be connected to the source/drain diffused regions are formed penetrating through the interlayer dielectric film. Thereafter, bit lines and capacitors are formed and connected to the plugs. After performing the above steps, manufacture of the semiconductor device 10 is accomplished.

In the method of manufacturing a semiconductor device according to the present embodiment, the dry etching for forming the gate trenches 16 does not etch the isolation film of the STI structure, whereby it is possible to prevent the voids, if formed in the isolation film, from being exposed from the surface of the isolation film 13. This suppresses occurring of the short-circuit failure caused by the voids between the gate electrodes 15.

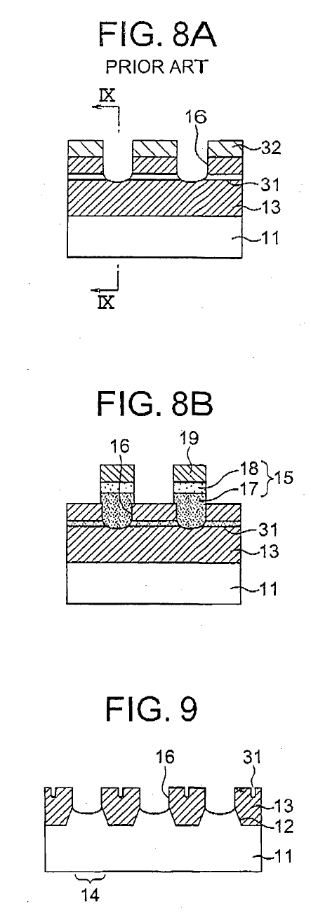

FIG. 9 is a sectional view of the conventional semiconductor device, taken along arrowed line IX-IX in FIG. 8A. The sectional surface shown in FIG. 9 corresponds to FIG. 6B of the above embodiment. In the conventional process for manufacturing a semiconductor device, as shown in FIG. 9, the dry etching for forming the gate trenches 16 may expose part of the voids 31 on the surface of the isolation film 13 of the STI structure. The part of voids 31 is extremely small in size, to thereby cause residual polysilicon particles being left within the voids 31 after patterning of the gate electrodes 15 by using a dry etching process. The residual polysilicon particles may cause a short-circuit failure between adjacent gate electrodes 15.

In contrast, in the process for manufacturing the semiconductor device according to the present embodiment, the voids 31 are not exposed on the surface of the insulating film after the dry etching for forming the gate trenches 16. Therefore, such a short-circuit failure can be avoided between the adjacent gate electrodes via the exposed voids 31.

Meanwhile, in order to avoid the etching of the isolation film 13, it may be considered to provide a photoresist mask on the isolation film 13, in place of the etching mask of the present embodiment, the photoresist mask having a rectangular opening on the intersection between the active regions 14 and the gate electrodes 15. However, it is difficult to form a corner having a small angle in the opening of the photoresist mask. If the opening has a round corner portion, the gate trenches 16 may possibly have a small depth in the vicinity of the round corner portion. In this case, another problem is emerged that a sufficient channel length cannot be secured in the RCAT MISFETs.

In contrast to the above problem, in the present embodiment, the etching mask configured by the hard mask pattern 22 and photoresist mask pattern 23, which intersects each other as shown in FIG. 7, prevents occurring of a round corner in the etching mask. This prevents a smaller depth of the gate trenches 16 from occurring in the vicinity of the corner, thereby assuring a sufficient channel length for the MISFETs.

Additionally, the resist 23 may be of a multi-layered structure having at least two layers. In this case, a high etching tolerance can be attained while increasing the positional accuracy in the etching irrespective of a smaller thickness.

As described above, in the semiconductor device of the above embodiment and manufactured by the method of the above embodiment, the gate trenches are not formed on the isolation film of STI structure. Therefore, even in the case where the void exist in the STI structure, the void can be prevented from being exposed in the formation of the gate trench. Thus, it is possible to prevent a short circuit from being established via the void.

With the method for manufacturing the semiconductor device of the above embodiment, in addition to the first stripes, second stripes are formed, which extend over the isolation film of the STI structure and intersect the first stripes. This prevents the gate trench from being formed on the isolation film. In addition, by separately forming the first stripes and the second stripes intersecting each other, the corners of the opening configured by these stripe patterns are substantially of a rectangle. Thus, the gate trenches have a sufficient depth in the vicinity of the corner of the etching mask.

In the method for manufacturing the semiconductor device of the present invention, the first stripes may be made of silicon nitride, while the second stripes may be made of photoresist. By forming the first stripes made of silicon nitride first and then the second stripes made of photoresist, the shape of the first stripes can be prevented from being affected by the formation of the second stripes.

It is to be noted that, in the semiconductor device manufactured by the method of the above embodiment, the array of the active regions need not be arranged in the column direction and the row direction which are exactly perpendicular to each other. The row direction and the column direction of the array may intersect at an acute angle or blunt angle, and the corner formed at the intersection between the hard mask and the photoresist mask may be a somewhat round corner.

While the invention has been particularly shown and described with reference to exemplary embodiment and modifications thereof, the invention is not limited to these embodiment and modifications. It will be understood by those of ordinary skill in the art that various changes in form and details may be made therein without departing from the spirit and scope of the present invention as defined in the claims.

What is claimed is:

1. A method for manufacturing a semiconductor device comprising:
forming an isolation region on a surface region of a semiconductor substrate to define an array of active regions isolated from on another;
for a mask having a pattern including a plurality of first stripes extending parallel to one another, said first stripes each extending over a portion of said active regions arranged in a row, and a plurality of second stripes extending parallel to one another to intersect said first stripes, said second stripes each extending over a portion of said isolation region located between adjacent columns of said active regions;
selectively etching said active regions by using said mask as an etching mask, to form a gate trench in each of active regions; and
forming MISFETs each including source/drain regions in one of said active regions and a gate electrode received in said gate trench formed in said one of said active regions.

2. The method according to claim 1, wherein said first stripes include silicon nitride.

3. The method according to claim 1, wherein said second stripes include photoresist.

4. The method according to claim 1, wherein said first stripes extend substantially perpendicular to said second stripes.

5. A semiconductor device comprising:
a semiconductor substrate;
an isolation region defining an array of active regions on said semiconductor substrate, said active regions having a top surface flush with a top surface of said isolation region and including a gate trench therein; and
a plurality of MISFETs formed in respective said active regions, a row of said MISFETs including a gate electrode having a first portion extending on said top surface of said isolation region and a second portion embedded in said gate trench.
